(19) United States
(12) Patent Application Publication
(10) Pub. No.: US 2023/0352284 A1
(43) Pub. Date: Nov. 2, 2023

(54) SYSTEM AND METHOD FOR DETECTING EXCURSION IN PLASMA PROCESSING

(71) Applicant: FORTH-RITE TECHNOLOGIES, LLC, Austin, TX (US)

(72) Inventors: Terry R. Turner, Austin, TX (US); Jerome R. Cannon, Austin, TX (US)

(21) Appl. No.: 18/139,428

(22) Filed: Apr. 26, 2023

Related U.S. Application Data
(60) Provisional application No. 63/335,935, filed on Apr. 28, 2022.

(51) Int. Cl. H01J 37/32; G01R 23/16

(52) U.S. Cl. CPC H01J 37/3299; H01J 37/32926; H01J 37/32357; G01R 23/16; H01J 2237/24564; H01J 2237/334; H01J 2237/057; H01J 37/3244

(57) ABSTRACT

An method for detecting excursion in plasma processing and controlling plasma processing is disclosed. The method includes the steps of tracking harmonics that are produced due to nonlinearity of an impedance of a plasma environment. The method includes the steps of creating a fingerprint of energy distribution in frequency space based on the tracked harmonics and comparing the created fingerprint with reference spectra of an ideal plasma processing to detect deviation of the fingerprint with the reference spectra. The method includes the steps of detecting an excursion in the plasma processing based on the detected deviation. The method includes the steps of generating recommendations to control the detected excursion. Such recommendations are generated based on the detected deviation and the associated historical data related to corrective action stored in a corrective action database.

### BACKGROUND

The present disclosure is U.S. Non-Provisional Application that claims the benefit of U.S. Provisional Application No. 63/335,935, filed Apr. 28, 2022; all of which is incorporated herein by reference.

### TECHNICAL FIELD

The present disclosure relates to the field of plasma processing, and in particular, relates to a system and method for detecting excursion in plasma processing and controlling the plasma processing.

### DESCRIPTION OF THE RELATED ART

Plasma processing refers to the use of plasma, a high-energy state of matter, to modify or alter properties of a wide range of materials to make them easier to paint, print or bond together. Plasma processing can be used to clean, activate, etch, or coat a surface of a material, such as a substrate. The plasma processing technique is widely used in the field of electronics, material science, and biotechnology. For example, the plasma processing technique is a dominant means of pattern transfer in microelectronic device fabrication that is commonly used in both semiconductor and display manufacturing. Typically, the plasma processing apparatus includes a plasma processing chamber, a gas delivery system, a power source such as a Radio Frequency (RF) power source, and a substrate holder. The plasma processing chamber is an enclosure that receives a supply of gas via the gas delivery system that is ionized by the electromagnetic waves produced by the power source. The electromagnetic waves lead to the separation of the atoms into positively charged ions and negatively charged electrons that interact with each other leading to a self-sustaining reaction that creates a plasma environment. Such plasma environments can be controlled by adjusting parameters of the plasma processing apparatus, such as the type of gas used, the pressure inside the plasma processing chamber, and the frequency and power of the electromagnetic waves.

However, excursions such as arcs, micro-arcs, or other plasma instability, can occur during plasma processing due to a variety of reasons such as fluctuations in gas flow rates, changes in temperature, pressure, or power levels, and variations in the composition of the plasma itself. For example, if the gas flow rate decreases during the plasm processing, then the plasma density may increase, resulting in over-etching or damage to the substrate. Similarly, if the temperature or pressure of the plasma chamber fluctuates, the plasma parameters may change, resulting in variations in the etch rate or deposition rate of the material being processed. Such plasma excursions result in shifted process results, reduced product yield, and increased system downtime. Thus, the detection of excursions during the plasma processing of substrates is essential to either stop or better define and control process conditions to reduce plasma excursions.

Therefore, detecting excursion and controlling the plasma process when the excursion has occurred to either stop the process or control the excursion is very important to mitigate the production of low-quality substrates. Some of the prior art references that disclose the excursion detection are given below:

U.S. Pat. No. 8,502,689 B2 discloses a system and a method for voltage-based plasma excursion detection. The patent '689 includes sensing a bias voltage from an RF power electrode disposed in a gas distribution system within the plasma chamber during plasma processing. The patent '689 includes filtering the bias voltage using a plurality of analog filters to obtain an output voltage signal. Further, the patent '689 discloses comparing the output voltage signal to a present voltage value, representing a plasma excursion event, to generate an alarm signal if the output voltage signal exceeds the present voltage value.

U.S. Pat. No. 8,587,321 B2 discloses a system and method for current-based plasma excursion detection. The patent '321 includes generating a time-varying magnetic field around the RF transmission line while the RF current is flowing through it to generate a time-varying electric field. Further, the patent '321 includes inducing the RF current by the time-varying electric field from the time-varying electric field to flow through the RF current probe to convert it into a voltage signal. The patent '321 further includes filtering the voltage signal to obtain an output voltage signal and comparing the output voltage signal to a present voltage value, representing a plasma excursion event, to generate an alarm signal if the output voltage signal exceeds the present voltage value.

Accordingly, the prior art references disclose the excursion detections that are based on monitoring a control input, such as the voltage and the current, provided to the plasma chamber during plasma processing. Thus, the excursion detection, as disclosed in the prior art references, is dependent on the power source of the plasma process and would fail when the excursion is because of the power source in the plasma process. Additionally, the prior art references fail to detect the reason behind the excursion and thus the prior art reference cannot be utilized to automatically control the excursion in the plasma processing.

Therefore, there is a need for an improved system and method for detecting excursion along with the source of excursion in plasma processing to overcome the above-mentioned drawbacks of the known technologies.

### BRIEF SUMMARY

One or more embodiments are directed to an excursion detection and plasma processing control system and method for detecting excursion in plasma processing and controlling the plasma processing.

An embodiment of the present disclosure discloses an excursion detection and control system for detecting excursion in plasma processing and controlling an in-situ plasma processing. The in-situ plasma processing may be utilized to deposit and/or remove a film on a substrate. The excursion detection and control system includes a transducer assembly to track one or more harmonics that are produced due to nonlinearity of an impedance in a plasma environment. The one or more harmonics are associated with voltage, current, or a combination thereof. In some embodiment of the present disclosure, the excursion detection and control system includes one or more spectrum analyzers to create a fingerprint of energy distribution in frequency space based on the tracked one or more harmonics. In order to create the fingerprint, the one or more spectrum analyzers calculate average and standard deviation of amplitude of the one or more harmonics when plasma and chemical conditions of the plasma processing are stable. After calculating average and standard deviation of the amplitudes, the one or more spectrum analyzers filter the one or more harmonics by removing harmonics from the tracked one or more harmonics that have the amplitude and the standard deviation less than a pre-defined threshold value In some embodiments of the present disclosure, the one or more spectrum analyzers compare the created fingerprint with a reference spectra of an ideal plasma processing to detect deviation of the fingerprint with the reference spectra in real-time. The reference spectra may be stored in a historical database and are selected based on one or more control inputs set by a user for the plasma processing. The one or more control inputs are based on purpose of the plasma processing, identification of a type of substrate being used, identification of an amount of substrate being used, identification of a pressure in the process chamber, identification of a type of gas being used, and/or identification of an amount of gas being used. In some embodiments, such deviation is created due to variation in controllable subassemblies of the plasma processing that includes incoming workpiece conditions, process chamber pressure, process gas mixture, Radio Frequency (RF) power, and/or electrode spacing in the process chamber.

In some embodiments of the present disclosure, the one or more spectrum analyzers detect an excursion in the plasma processing based on the detected deviation of the fingerprint with the reference spectra, such as the excursion is detected when the detected deviation is more than a control limit that is associated with the reference spectra. The excursion detection and control system also includes a recommendation module to generate one or more recommendations to control the detected excursion. The one or more recommendations are generated based on the detected deviation, associated historical data related to corrective action stored in a corrective action database, or a combination thereof. In some embodiments of the present disclosure, the recommendation module matches the detected deviation with one or more deviations stored in the corrective action database to determine a reason behind the excursion and provide the one or more recommendations. The one or more recommendations are related to controlling workpiece conditions, controlling process chamber pressure, controlling gas mixture, controlling RF power, and/or controlling electrode spacing.

In an embodiment of the present disclosure, the excursion detection and control system further includes a controller for controlling an associated controllable subassembly based on the one or more recommendations, such that the excursion is reduced in the subsequent substrates. In some embodiments of the present disclosure, the controller stops the plasma processing based on the detected excursion, such that the subsequent substrates in the plasma processing are saved from the excursion. In an embodiment, the controller can stop accepting additional substrates until the excursion is cleared.

In some embodiment of the present disclosure, each of the one or more spectrum analyzers includes any combination of an RF input attenuator, a pre-selector, a low-pass filter, a local oscillator, a mixer, an Intermediate Frequency (IF) gain module, an IF filter, an analog-to-digital converter, a digital IF, a fast Fourier transform module, a video bandwidth filter, and a display, working in tandem.

An embodiment of the present disclosure discloses an excursion detection and control system for detecting excursion in downstream plasma processing and controlling plasma processing. The excursion detection and control system includes an electrode assembly inserted in an exhaust line of a plasma processing chamber to receive its effluent as a feed gas. In some embodiments, the excursion detection and control system includes a power generator to generate an energy for ionizing the received feed gas in the electrode assembly, such that the ionization of the feed gas leads to a formation of a plasma environment to create a small capacitively coupled plasma. In some embodiments, the excursion detection and control system includes a dual directional coupler coupled between the electrode assembly and the power generator to track one or more harmonics that are produced due to non-linearity of an impedance in the plasma environment.

In some embodiments of the present disclosure, the excursion detection and control system includes one or more spectrum analyzers to create a fingerprint of energy distribution in frequency space based on the tracked one or more harmonics. To create the fingerprint, the one or more spectrum analyzers calculate average and standard deviation of amplitude of the one or more harmonics when plasma and chemical conditions of the plasma processing are stable. After calculating average and standard deviation of the amplitude, the one or more spectrum analyzers filter the one or more harmonics by removing harmonics from the tracked one or more harmonics that have the amplitude and the standard deviation less than a pre-defined threshold value.

In some embodiments of the present disclosure, the one or more spectrum analyzers compare the created fingerprint with reference spectra of an ideal plasma processing, stored in a historical database, to detect deviation of the fingerprint with the reference spectra in real-time. In some embodiments of the present disclosure, the one or more spectrum analyzers detect an excursion in the plasma processing based on the detected deviation of the fingerprint with the reference spectra. In some embodiments, the excursion is detected when the detected deviation is more than a control limit that is associated with reference spectra.

In some embodiments of the present disclosure, the excursion detection and control system includes a recommendation module to generate one or more recommendations to control the detected excursion. The one or more recommendations are generated based on the detected deviation and associated historical data related to corrective action stored in a corrective action database. In some embodiments, the recommendation module matches the detected deviation with one or more deviations stored in the corrective action database to determine a reason behind the excursion and provide the one or more recommendations. The one or more recommendations are related to controlling workpiece conditions, controlling process chamber pressure, controlling gas mixture, controlling RF power, and/or controlling electrode spacing.

In some embodiments of the present disclosure, the excursion detection and control system includes a controller for controlling an associated controllable subassembly based on the one or more recommendations, such that the excursion is reduced in the subsequent substrates. In some embodiments, the controller stops the plasma processing based on the detected excursion, such that the subsequent substrates in the plasma processing are saved from the excursion.

An embodiment of the present disclosure discloses a method for detecting excursion in plasma processing and controlling plasma processing. The method includes the steps of tracking one or more harmonics that are produced due to nonlinearity of an impedance of a plasma environment. The one or more harmonics are associated with voltage, current, or a combination thereof. In some embodiments of the present disclosure, the method includes the steps of creating a fingerprint of energy distribution in frequency space based on the tracked one or more harmonics. In order to create the fingerprint, the method includes the steps of calculating average and standard deviation of amplitude of the one or more harmonics when plasma and chemical conditions of the plasma processing are stable. Upon calculating the average and standard deviation of amplitude, the method includes the steps of filtering the one or more harmonics by removing harmonics from the tracked one or more harmonics that have the amplitude and the standard deviation less than a pre-defined threshold value.

In some embodiments of the present disclosure, the method includes the steps of comparing the created fingerprint with a reference spectra of an ideal plasma processing to detect deviation of the fingerprint with the reference spectra in real-time. Such reference spectra are stored in a historical database. In some embodiments of the present disclosure, the method includes the steps of detecting an excursion in the plasma processing based on the detected deviation of the fingerprint with the reference spectra. In some embodiments of the present disclosure, the excursion is detected when the detected deviation is more than a control limit that is associated with the reference spectra.

In some embodiments of the present disclosure, the method includes the steps of generating one or more recommendations to control the detected excursion. Such one or more recommendations are generated based on the detected deviation and the associated historical data related to corrective action stored in a corrective action database.

The features and advantages of the subject matter here will become more apparent in light of the following detailed description of selected embodiments, as illustrated in the accompanying FIGURES. As will be realized, the subject matter disclosed is capable of modifications in various respects, all without departing from the scope of the subject matter. Accordingly, the drawings and the description are to be regarded as illustrative in nature.

### BRIEF DESCRIPTION OF THE DRAWINGS

The present subject matter will now be described in detail with reference to the drawings, which are provided as illustrative examples of the subject matter so as to enable those skilled in the art to practice the subject matter. Notably, the FIGURES and examples are not meant to limit the scope of the present subject matter to a single embodiment, but other embodiments are possible by way of interchange of some or all of the described or illustrated elements and, further, wherein:

FIG. 1 illustrates a block diagram of an excursion detection and control system for detecting an excursion in plasma processing and controlling in-situ plasma processing, in accordance with various embodiments of the present disclosure;

FIG. 2 illustrates a transducer assembly, in accordance with an embodiment of the present disclosure;

FIG. 3 illustrates an example of harmonics generated due to the nonlinearity of the plasma environment, in accordance with an embodiment of the present disclosure;

FIG. 4 illustrates a block diagram of a spectral analyzer, in accordance with an embodiment of the present disclosure;

FIG. 5 illustrates exemplary one or more recommendations provided by a recommendation module, in accordance with an exemplary embodiment of the present disclosure;

FIG. 6 illustrates a block diagram of an excursion detection and control system for detecting excursion in a downstream plasma processing and controlling downstream plasma processing, in accordance with various embodiments of the present disclosure;

FIG. 7 illustrates process fingerprints for different processes, created using spectral analysis in accordance with an exemplary embodiment of the present disclosure;

FIG. 8A illustrates an example voltage spectrum during the excursion, in accordance with an exemplary embodiment of the present disclosure;

FIG. 8B illustrates an example voltage spectrum during normal conditions, in accordance with an exemplary embodiment of the present disclosure;

FIG. 9 illustrates an example attachment attached at an exhaust line of the plasma chamber, in accordance with an embodiment of the present disclosure;

FIG. 10 illustrates a flowchart of a method for detecting excursion in plasma processing and controlling plasma processing, in accordance with an embodiment of the present disclosure; and

FIG. 11 illustrates an exemplary computer system in which or with which embodiment of the present disclosure may be utilized.

Other features of embodiments of the present disclosure will be apparent from accompanying drawings and detailed description that follows.

### DETAILED DESCRIPTION

In the following description, for purposes of explanation, numerous specific details are set forth in order to provide a thorough understanding of the present disclosure. It will be apparent, however, to one skilled in the art that the present disclosure is not limited to these specific details. In other instances, structures and devices are shown in block diagram form only in order to avoid obscuring the present technology.

The terms “connected” or “coupled” and related terms are used in an operational sense and are not necessarily limited to a direct connection or coupling. Thus, for example, two devices may be coupled directly, or via one or more intermediary media or devices. As another example, devices may be coupled in such a way that information can be passed there between, while not sharing any physical connection. Based on the disclosure provided herein, one of ordinary skill in the art will appreciate a variety of ways in which connection or coupling exists in accordance with the aforementioned definition.

If the specification states a component or feature “may”, “can”, “could”, or “might” be included or have a characteristic, that particular component or feature is not required to be included or have the characteristic.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments.

Further, the terms “semiconductor wafer,” “wafer,” “substrate,” “wafer substrate,” and “partially fabricated integrated circuit” are used interchangeably. One of the ordinary skills in the art would understand that the term “partially fabricated integrated circuit” can refer to a silicon wafer during any of many stages of integrated circuit fabrication thereon. A wafer used in the semiconductor device industry typically has a diameter of 200 mm, or 300 mm, or 450 mm. The following detailed description assumes the disclosure is implemented on a wafer. However, the disclosure is not so limited. The workpiece may be of various shapes, sizes, and materials. In addition to semiconductor wafers, other work pieces that may take advantage of this disclosure include various articles such as printed circuit boards, magnetic recording media, magnetic recording sensors, mirrors, optical elements including pixelated displays, micro-mechanical devices, and the like.

Fabrication of certain semiconductor devices involves etching features into a material or materials. The material may be a single layer of material or a stack of materials. In some cases, a stack includes alternating layers of material (e.g., silicon nitride and silicon oxide). One example etched feature is a cylinder. In various embodiments herein, features are etched in a substrate (typically a semiconductor wafer) having dielectric, semiconductor, and/or conductor material on the surface. The etching processes are generally plasma-based etching processes. A feature is a recess on the surface of a substrate. Features can have many different shapes including, but not limited to, cylinders, rectangles, squares, other polygonal recesses, trenches, etc. Examples of etched features include various gaps, holes or vias, trenches, and the like.

In certain embodiments, an excursion detection and control system is disclosed. The excursion detection and control system may be coded or otherwise implemented in a plasma processing apparatus such that when it executes it provides real-time monitoring of the plasma process in the plasma processing apparatus. In some implementations, the system determines or assists in determining the excursion of the plasma processing.

Further, the plasma processing is modeled and/or monitored as described herein and may be characterized by various features. For example, the process may be characterized by the type of material or substrate being plasma processed for etching. The etched material may be a conductor, a dielectric, a semiconductor, or any combination thereof. Further, the etched material may be monolithic or layered. It may be used to form memory and/or logic devices. Examples of dielectric materials for etching include silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular example materials include stoichiometric and non-stoichiometric formulations of Si02, SiN, SiON, SiOC, SiCN, etc. Examples of conductor materials include, but are not limited to, nitrides such as titanium nitride and tantalum nitride and metals such as cobalt, aluminum, ruthenium, hafnium, titanium, tungsten, platinum, iridium, palladium, manganese, nickel, iron, silver, copper, molybdenum, tin, and various alloys, including alloys of these metals. Examples of semiconductor materials include, but are not limited to, doped and undoped silicon, germanium, gallium arsenide, etc. Any of the above conductors, semiconductors, and dielectrics may have a distinct morphology such as polycrystalline, amorphous, single crystal, and/or microcrystalline. Other materials that may be etched include, but are not limited to, CoFeB, Ge2Sb2Te2, InSbTe compounds, Ag—Ge—S compounds, and Cu—Te—S compounds. The concept can be extended to materials like NiOx, SrTiOx, perovskite (CaTiO3), PrCaMnO3, PZT (PbZr1-xTixO3), (SrBiTa)O3, and the like.

The etch process may be primarily physical (e.g., non-reactive ion bombardment), primarily chemical (e.g., chemical radicals with only small directional bombardment), or any combination thereof. When a chemical etch is included, the chemical reactant may be any one or more of a variety of etchants including, for example, reactants containing fluorocarbons, fluorine, oxygen, chlorine, etc. Example etchants include chlorine (Cl2), boron trichloride (BC13), sulfur hexafluoride (SF6), nitrogen trifluoride (NF3), dichlorodifluoromethane (CCl2F2), phosphorus trifluoride (PF3), trifluoromethane (CHF3), carbonyl fluoride (COF2), oxygen (O2), carbon tetrachloride (CCl4), silicon tetrachloride (SiCl4), carbon monoxide (CO), nitric oxide (NO), methanol (CH3OH), ethanol (C2H5OH), acetylacetone (C5H8O2), hexafluoroacetylacetone (C5H2F6O2), thionyl chloride (50Cl2), thionyl fluoride (SOF2), acetic acid (CH3COOH), pyridine (C5H5N), formic acid (HCOOH), and combinations thereof. In various embodiments, a combination of these etching reactants is used.

Embodiments described herein may be discussed in the general context of computer-executable instructions residing on some form of computer-readable storage media, such as program modules, executed by one or more computers or other devices. By way of example, and not limitation, computer-readable storage media may include non-transitory computer-readable storage media and communication media; non-transitory computer-readable media include all computer-readable media except for a transitory, propagating signal. Generally, program modules include routines, programs, objects, components, data structures, etc., that perform particular tasks or implement particular abstract data types. The functionality of the program modules may be combined or distributed as desired in various embodiments.

Some portions of the detailed description that follows are presented and discussed in terms of a process or method. Although steps and sequencing thereof are disclosed in figures herein describing the operations of this method, such steps and sequencing are exemplary. Embodiments are well suited to performing various other steps or variations of the steps recited in the flowchart of the figure herein and in a sequence other than that depicted and described herein. Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

In some implementations, the flowchart and block diagrams in the Figures illustrate the architecture, functionality, and operation of possible implementations of apparatus (systems), methods, and computer program products according to various implementations of the present disclosure. Each block in the flowchart and/or block diagrams, and combinations of blocks in the flowchart and/or block diagrams, may represent a module, segment, or portion of code, which includes one or more executable computer program instructions for implementing the specified logical function(s)/act(s). These computer program instructions may be provided to a processor of a general-purpose computer, special-purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of order noted in the figures. For example, two blocks shown in succession may, in fact, be executed substantially concurrently, or the blocks may sometimes be executed in the reverse order, depending upon the functionality involved.

Embodiments of the present disclosure include various steps, which will be described below. The steps may be performed by hardware components or may be embodied in machine-executable instructions, which may be used to cause a general-purpose or special-purpose processor programmed with the instructions to perform the steps. Alternatively, steps may be performed by a combination of hardware, software, firmware, and/or by human operators.

Thus, for example, it will be appreciated by those of ordinary skill in the art that the diagrams, schematics, illustrations, and the like represent conceptual views or processes illustrating systems and methods embodying this disclosure. The functions of the various elements shown in the figures may be provided through the use of dedicated hardware as well as hardware capable of executing associated software. Similarly, any switches shown in the figures are conceptual only. Their function may be carried out through the operation of program logic, through dedicated logic, through the interaction of program control and dedicated logic, or even manually, the particular technique being selectable by the entity implementing this disclosure. Those of ordinary skill in the art further understand that the exemplary hardware, software, processes, methods, and/or operating systems described herein are for illustrative purposes and, thus, are not intended to be limited to any particular named.

Embodiments of the present disclosure relate to an excursion detection and control system for detecting excursion in plasma processing and controlling an in-situ plasma processing, an excursion detection and control system for detecting excursion in a downstream plasma processing and controlling downstream plasma processing, and an method for detecting excursion in a downstream plasma processing and controlling plasma processing. The excursion detection and control system includes tracking one or more harmonics that are produced due to nonlinearity of an impedance in a plasma environment. The one or more harmonics are associated with voltage, current, or a combination thereof. Further, the excursion detection and control system includes creating a fingerprint of energy distribution in frequency space based on the tracked one or more harmonics and comparing, in real-time, the created fingerprint with reference spectra of an ideal plasma processing, stored in a historical database, to detect deviation of the fingerprint with the reference spectra. The excursion detection and control system further includes detecting an excursion in the plasma processing based on the detected deviation of the fingerprint with the reference spectra. Additionally, the excursion detection and control system includes generating one or more recommendations to control the detected excursion. The one or more recommendations are generated based on the detected deviation, associated historical data related to corrective action stored in a corrective action database, or a combination thereof.

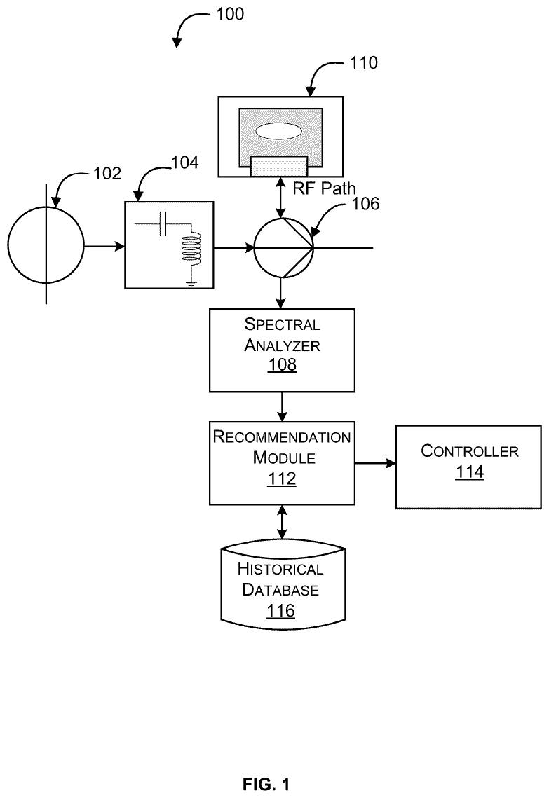

FIG. 1 illustrates a block diagram of an excursion detection and control system 100 for detecting an excursion in plasma processing and controlling in-situ plasma processing. In-situ plasma processing is a technique in which several processes for plasma processing are carried out in sequence without exposing a substrate to air between the processes. The in-situ plasma processing requires placing the substrate in a process chamber 110 of the plasma processing apparatus (not shown). The process chamber 110 may also be termed as a plasma processing chamber 110 for the purpose of the explanation of the disclosure. Upon placement of the substrate, a gas is released in the plasma processing chamber 110. In an embodiment of the present disclosure, the gas may be an inert gas such as argon and neon. In another embodiment of the present disclosure, the gas may be a reactive gas such as oxygen. In yet another embodiment of the present disclosure, air may be used instead of a particular gas without departing from the scope of the disclosure. The substrate kept in the plasma processing chamber 110 for plasma processing may be associated with a semiconductor, display manufacturing, or a combination thereof. The plasma processing may be performed for depositing or removing a film on the substrate. Further, the excursion may correspond to any deviation from a normal process condition during such plasma processing. Such deviation may be due to, without any limitation, variation in controllable subassemblies of the plasma processing that includes incoming workpiece conditions, process chamber pressure, process gas mixture, Radio Frequency (RF) power, and/or electrode spacing in the process chamber.

In an embodiment of the present disclosure, the excursion detection and control system 100 may include a power generator 102, a local matching network 104, a transducer assembly 106, one or more spectral analyzers 108, the process chamber 110, a recommendation module 112, a controller 114, and a historical database 116. The power generator 102 may generate energy in a controlled manner for ionizing the gas in the plasma processing chamber 110. In an embodiment, the power generator 102 may include a Radio Frequency (RF) power generator, an electromagnetic power generator, and/or a Remote Plasma Source (RPS). Accordingly, the energy generated by the power generator 102 may include a high-frequency electromagnetic wave. For example, the power generator 102 may generate a high-frequency wave having a single sinusoidal frequency with a nominal 50-ohm output impedance. In order to ionize the gas in the plasma processing chamber 110, the generated energy may be transferred to one or more electrodes installed in the plasma processing chamber 110, which in turn may emit the generated energy for ionization of the gas. Further, the ionization of the gas may create a plasma environment that may facilitate the plasma processing of the substrate.

In an embodiment of the present disclosure, the created plasma environment may have a nonlinear impedance such as a non-50-ohm impedance and a complex nonlinear impedance. The complex nonlinear impedance may be because the voltage and current of the plasma environment are non-proportional and may be highly complex. Such nonlinearity of the impedance of the plasma environment leads to the formation of harmonics in the plasma processing apparatus.

In order to minimize such harmonics, the local matching network 104 may match the impedance of the high-frequency wave generated by the power generator 102 with the impedance of the plasma environment. However, load side of the impedance matching network 104 is typically nonlinear thus, the harmonics of the incident frequency at the load side are not eliminated. Such harmonics may be associated with voltage, current, or a combination thereof. It may be noted that such harmonics have amplitudes that vary over time as etching processes progress from the beginning to the end of pattern delineation in a film on the surface of the substrate and during the occurrence of an excursion.

In an embodiment of the present disclosure, the transducer assembly 106 may track the created one or more harmonics. In an embodiment, the transducer assembly 106 may include a voltage-sensitive transducer to track the voltage harmonics. In another embodiment, the transducer assembly 106 may include a current-sensitive transducer to track the current harmonics, whereas a third may contain both.

In an embodiment of the present disclosure, the one or more spectrum analyzers 108 may analyze the tracked one or more harmonics. In one instance, one spectrum analyzer 108 may be utilized to track both the voltage harmonics and the current harmonics. In another instance, different spectrum analyzers 108 may be utilized for the voltage harmonics and the current harmonics. In an embodiment of the present disclosure, the one or more spectrum analyzers 108 may utilize RF spectroscopy to analyze the tracked one or more harmonics.

In an embodiment of the present disclosure, the one or more spectrum analyzers 108 may create a fingerprint of energy distribution in frequency space based on the tracked one or more harmonics. Such energy distribution may be associated with amplitude of the tracked one or more harmonics. In order to create the fingerprint, the one or more spectrum analyzers 108 may determine when plasma and chemical conditions of the plasma processing are stable. During such a portion of plasma processing, the one or more spectrum analyzers 108 may calculate an average and a standard deviation of amplitude of the one or more harmonics. Further, the one or more spectrum analyzers 108 may filter the one or more harmonics by removing such harmonics from the tracked one or more harmonics that have an amplitude and the standard deviation less than a pre-defined threshold value. In this way, the harmonics having a low signal-to-noise ratio may automatically be removed from the tracked one or more harmonics.

In an embodiment of the present disclosure, the one or more spectrum analyzers 108 may compare the created fingerprint with a reference spectra of an ideal plasma processing to detect deviation of the fingerprint with the reference spectra. Such reference spectra may be stored in the historical database 116 and the one or more spectrum analyzers 108 may select such reference spectra based on one or more control inputs set by a user for the plasma processing. The one or more control inputs may, without any limitation, be based on a purpose of the plasma processing, identification of a type of substrate being used, identification of an amount of substrate being used, identification of a pressure in the process chamber, identification of a type of gas being used, identification of an amount of gas being used, or a combination thereof. Further, the one or more spectrum analyzers 108 may check if the detected deviation is more than a control limit to detect an excursion in the plasma processing based on the detected deviation of the fingerprint with the reference spectra. It may be understood that the control limits may be associated with the referenced spectra.

In an embodiment of the present disclosure, the recommendation module 112 may generate one or more recommendations to control the detected excursion. In order to generate the one or more recommendations, the recommendation module 112 may fetch associated historical data related to the corrective action from a corrective action database in the historical database 116. Upon fetching the associated historical data, the recommendation module 112 may match the detected deviation with one or more deviations stored in the corrective action database to determine a reason behind the excursion. Further, the recommendation module 112 utilizes the determined reason to provide the one or more recommendations such as, but not limited to, controlling workpiece conditions, controlling process chamber pressure, controlling gas mixture, controlling RF power, and controlling electrode spacing. The recommendation module 112 has been explained in detail in the following paragraphs.

In an embodiment of the present disclosure, the controller 114 may control an associated control subassembly of the plasma processing apparatus based on the one or more recommendations to reduce the excursion in the subsequent substrates used in the plasma processing. Such control subassemblies may, without any limitation, include an incoming workpiece controller, a pressure gauge, a gas valve, a power source, an electrode spacing controller, and other controllable subassemblies. In another embodiment of the present disclosure, the controller 114 may stop the plasma processing based on the detected excursion, such that the subsequent substrates in the plasma processing are saved from the excursion. In one implementation, the controller 114 may be an ON-OFF controller to provide a digital output signal that switches OFF one or more controllable subassemblies of the plasma processing apparatus to control the excursion or stop the plasma processing. In another implementation, the controller 114 may be a smart controller, such as a fuzzy logic controller, to turn OFF the one or more controllable subassemblies of the plasma processing apparatus to control the excursion or stop the plasma processing based on the detected excursion and one or more recommendations.

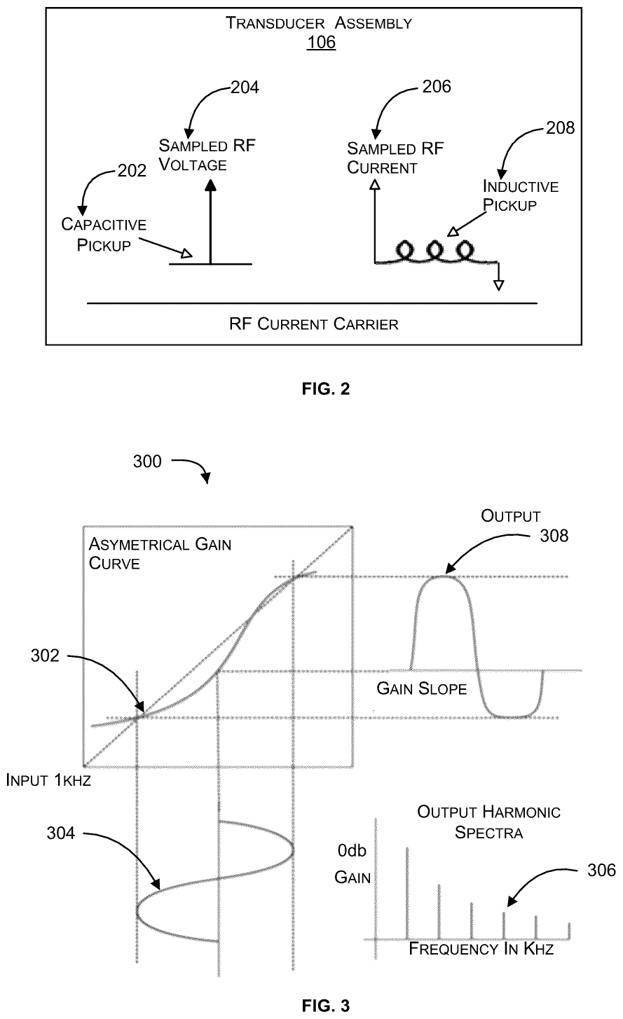

FIG. 2 illustrates the transducer assembly 106, in accordance with an embodiment of the present disclosure. In an embodiment of the present disclosure, the transducer assembly 106 includes a voltage-sensitive transducer and a current-sensitive transducer. The voltage-sensitive transducer includes a capacitive pickup 202 to track the voltage harmonics and convert them into voltage electrical signals via sampled RF voltage 204. Further, the current-sensitive transducer includes an inductive pickup 208 to track the current harmonics and convert them into a current electrical signal via sampled RF current 206.

FIG. 3 illustrates generation of harmonics 300 due to nonlinearity of plasma environment, in accordance with an embodiment of the present disclosure. In an embodiment of the present disclosure, the plasma environment, which has a nonlinear conductivity 302 in response to a sinusoidal input wave 304 having an input frequency of 1 kHz. As illustrated, the output 308 will be non-sinusoidal due to the nonlinear conductivity of the plasma medium. The mis-shapened output is no longer a single frequency, but rather is the sum of harmonic frequencies. Such even-order and odd-order distortion products are the created harmonics of the plasma processing apparatus.

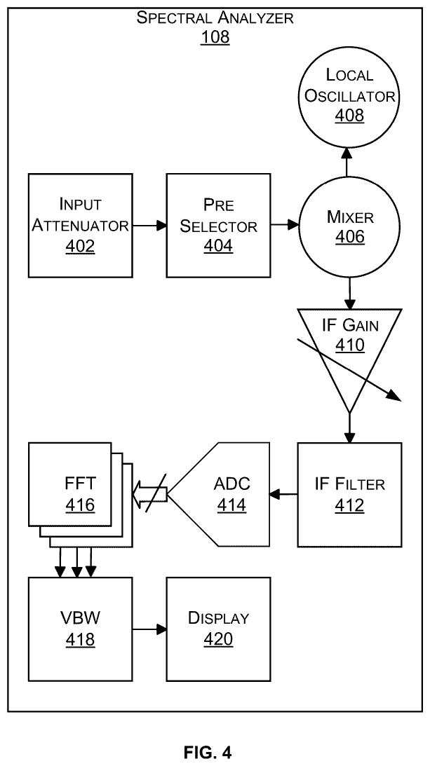

FIG. 4 illustrates a block diagram of the spectral analyzer 108, in accordance with an embodiment of the present disclosure. In an embodiment of the present disclosure, the spectral analyzer 108 includes an RF input attenuator 402, a pre-selector 404, a low-pass filter, a local oscillator 408, a mixer 406, an Intermediate Frequency (IF) gain module 410, an Intermediate Frequency (IF) filter 412, an analog-to-digital converter 414, a fast Fourier transform module 416, a video bandwidth filter 418, and a display 420. In an embodiment, the RF input attenuator 402 receives an input signal and controls the level of the input signal by reducing signal strength. Next, the controlled signal is provided to the pre-selector 404 or a low-pass filter to allow the filter of the signal to a required frequency. After filtering, the signal is provided to the mixer 406 which is communicatively coupled to the local oscillator 408 for changing the frequency of the signal. The IF gain module 410 and IF filter 412 may operate in tandem to return the gain at the intermediate frequency. After that, the analog-to-digital converter 414 converts the signal into a digital form i.e., digital IF such that the fast Fourier transform module 416 may convert it into individual spectral components and thereby provide frequency information about the signal. The Video Bandwidth (VBW) filter 418 may filter the noise to smooth the video traces in the individual spectral components provided by the fast Fourier transform module 416 to be displayed on the display 420.

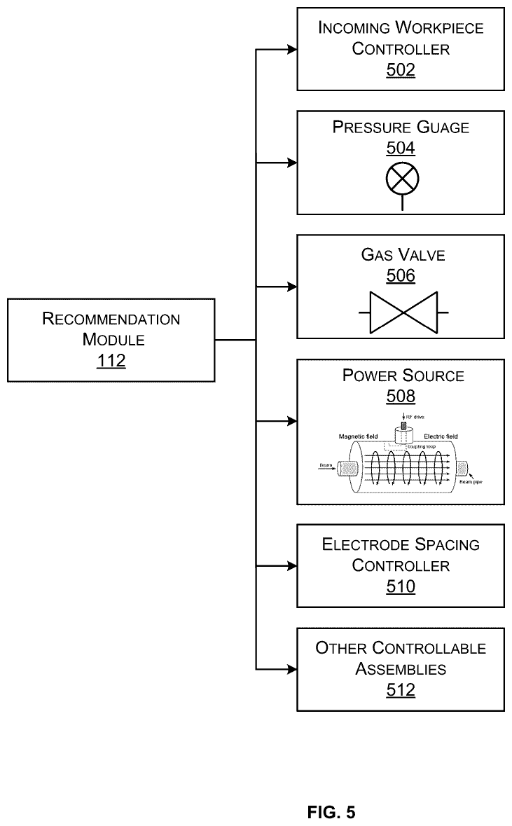

FIG. 5 illustrates exemplary one or more recommendations provided by the recommendation module 112, in accordance with an exemplary embodiment of the present disclosure. In an embodiment of the present disclosure, the recommendation module 112 may determine a reason behind the excursion and provide the one or more recommendations based on the determined reason. Such one or more recommendations are associated with controlling the one or more subassemblies of the plasma processing apparatus. In a non-limiting example, the recommendation module 112 may determine that an over-etching of the substrate is because of an increased plasma density due to a low gas flow rate, thus the recommendation module 112 may generate a recommendation to control the gas valve 506 to increase the gas flow rate. Similarly, the recommendation module 112 may generate, without any limitation, a recommendation to control incoming workpiece condition via controlling incoming workpiece controller 502, control pressure in the process chamber 110 via controlling pressure gauge 504, control RF power via controlling power source 508, control electrode spacing via electrode spacing controller 510, and control other controllable parameters via other controllable assemblies 512.

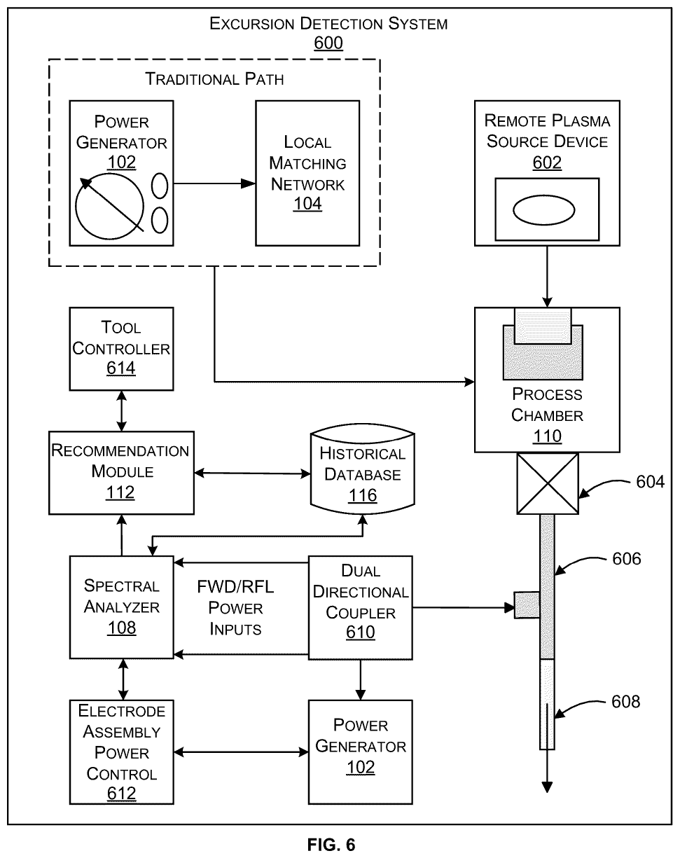

FIG. 6 illustrates a block diagram of an excursion detection and control system 600 for detecting excursion in a downstream plasma processing and controlling downstream plasma processing, in accordance with various embodiments of the present disclosure. The downstream plasma processing refers to a configuration where the plasma may be generated remotely relative to a process chamber 110 and only reactive species produced by the remote plasma reach the process chamber 110. In an embodiment, a remote plasma source 602 may be installed remotely from the process chamber 110. In contrary to the traditional in-situ plasma processing, where the plasma is generated directly above the substrate and ions can play an important part in the reaction process, the proposed excursion detection and control system 600 is designed to work even for remote plasma processing setup where a remote plasma source device 602 generates plasma at a distance from the substrate and only reactive species produced by the plasma reach the process chamber 110. With no plasma in the process chamber, there is no RF impedance to measure so, to implement impedance measurements, an electrode assembly 606 can be installed into the fore line and a small localized plasma is created at this location. For standard production, chamber cleans, measurement of the voltage, current, and phase at the supplied frequency (e.g., 13.56 MHz) driving the electrode assembly 606 is observed to determine excursion for each process. In an embodiment of the present disclosure, the excursion detection and control system 600 may include an exhaust line 604, an electrode assembly 606, a vacuum pump 608, a dual directional coupler 610, a power generator 102, an electrode assembly power controller 612, one or more spectral analyzers 108, a recommendation module 112, a tool controller 614, and a historical database 116. The exhaust line 604 may be formed in the plasma processing chamber 110, such that effluents from the plasma processing may be egressed from the plasma processing chamber 110 through the exhaust line 604. In an embodiment, the vacuum pump 608 pulls out the effluents from the plasma processing chamber 110.

In an embodiment of the present disclosure, the electrode assembly 606 may be inserted in the exhaust line 604 to receive the egressed effluents as a feed gas. In an embodiment, the power generator 102 may generate energy for ionizing the received feed gas in the electrode assembly 606. Further, the ionization of the received feed gas leads to the formation of a plasma environment in the electrode assembly 606 to create a small capacitively coupled plasma. In an embodiment of the present disclosure, the electrode assembly power controller 612 may be coupled to the power generator 102 to control the amount of power being supplied by the power generator 102. Thus, the electrode assembly power controller 612 may facilitate modification of frequency and power of the generated energy to match with the plasma environment.

In an embodiment of the present disclosure, the dual directional coupler 610 may be coupled between the electrode assembly 606 and the power generator 102. Thus, the dual directional coupler 610 can provide both sampled forward power to the electrode assembly 606 and sampled reflected power from the electrode assembly 606 as outputs. These samples having been exposed to the nonlinear conductivity of plasma will contain harmonics.

In an embodiment of the present disclosure, the one or more spectrum analyzers 108 may create a fingerprint of energy distribution in frequency space based on the tracked one or more harmonics and compare the created fingerprint with a reference spectra of an ideal plasma processing to detect deviation of the fingerprint with the reference spectra. Such deviation may further be utilized for detecting an excursion in the plasma processing. For the sake of brevity, the one or more spectrum analyzers 108 are not explained again, as they are already explained in detail in previous paragraphs.

In an embodiment of the present disclosure, the recommendation module 112 may generate one or more recommendations to control the detected excursion. For the sake of brevity, the recommendation module 112 is not explained again, as it is already explained in detail in previous paragraphs.

In an embodiment of the present disclosure, the tool controller 614 may control an associated control subassembly of the plasma processing apparatus based on the one or more recommendations to reduce the excursion in the subsequent substrates used in the plasma processing. Such control subassemblies may, without any limitation, include an incoming workpiece controller, a pressure gauge, a gas valve, a power source, an electrode spacing controller, and other controllable subassemblies. In another embodiment of the present disclosure, the tool controller 614 may stop the plasma processing based on the detected excursion, such that the subsequent substrates in the plasma processing are saved from the excursion. In one implementation, the tool controller 614 may be an ON-OFF controller to provide a digital output signal that switches OFF one or more controllable subassemblies of the plasma processing apparatus to control the excursion or stop the plasma processing. In another implementation, the tool controller 614 may be a smart controller, such as a fuzzy logic controller, to turn OFF the one or more controllable subassemblies of the plasma processing apparatus to control the excursion or stop the plasma processing based on the detected excursion and one or more recommendations.

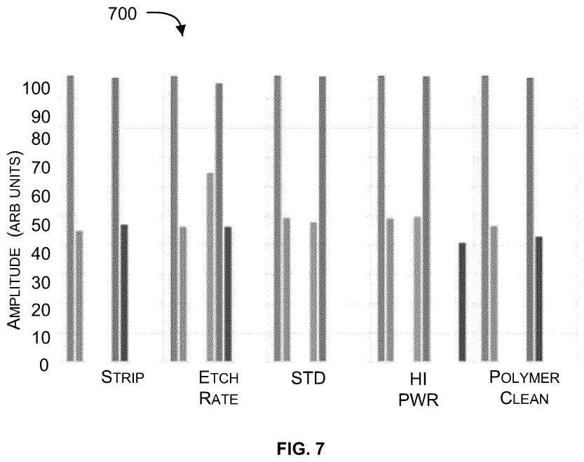

FIG. 7 illustrates process fingerprints 700 of different processes, created using spectral analysis in accordance with an exemplary embodiment of the present disclosure. The process fingerprints can be used to determine the excursion for each process of the plasma processing, such as strip, etch rate, standard, high power, and polymer cleaning. As illustrated, the inverted spectrum of the power generator 13.56 MHz power by process voltage spectra are equal to forward power spectra and current spectra are equal to reflected power spectra.

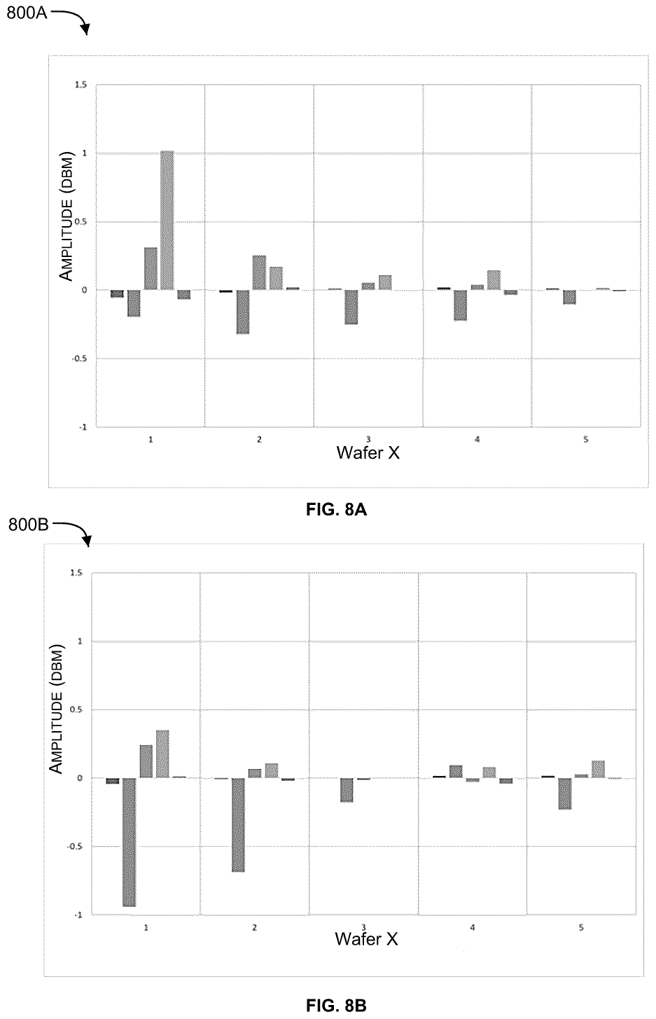

FIG. 8A illustrates an example voltage spectrum 800A during the excursion, in accordance with an exemplary embodiment of the present disclosure. FIG. 8B illustrates an example voltage spectrum 800B during normal conditions, in accordance with an exemplary embodiment of the present disclosure. For the sake of brevity, FIGS. 8A and 8B have been explained together. In an embodiment of the present disclosure, the control limit for excursion detection may be 1 dBM. As illustrated, in FIGS. 8A and 8B, the wafer X may exceed the control limit of 1 DbM during the excursion and may be within the control limit of 1 DbM during the normal conditions, respectively.

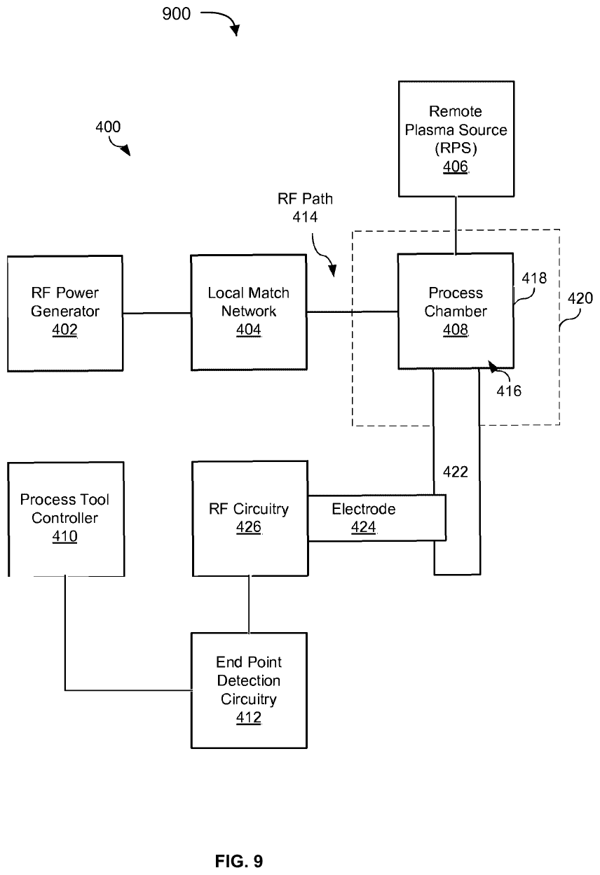

FIG. 9 illustrates an example attachment 900 attached at the exhaust line 604 of the plasma chamber 110, in accordance with an embodiment of the present disclosure. The attachment 900 may include the electrode assembly 606 that receives the egressed effluents, from the process chamber 110, as a feed gas. In an embodiment of the present disclosure, the electrode assembly 606 may be made of a suitable metal electrodes which create a capacitively coupled plasma in the exhaust line. The plasma environment formed during the creation of the plasma 906 may have a nonlinear impedance that may generate harmonics. Such generated harmonics may be tracked by an RF V-I probe 908 coupled between the power generator 102 and the electrode assembly 606 for one or more conventional uses such as monitoring RF discharge or troubleshooting. Further, the spectral analyzer 108 may be coupled to the electrode assembly 606 to receive both the received forward power and the reflected power from the electrode assembly 606 for analysis to detect the excursion of the plasma processing, as disclosed in previous paragraphs.

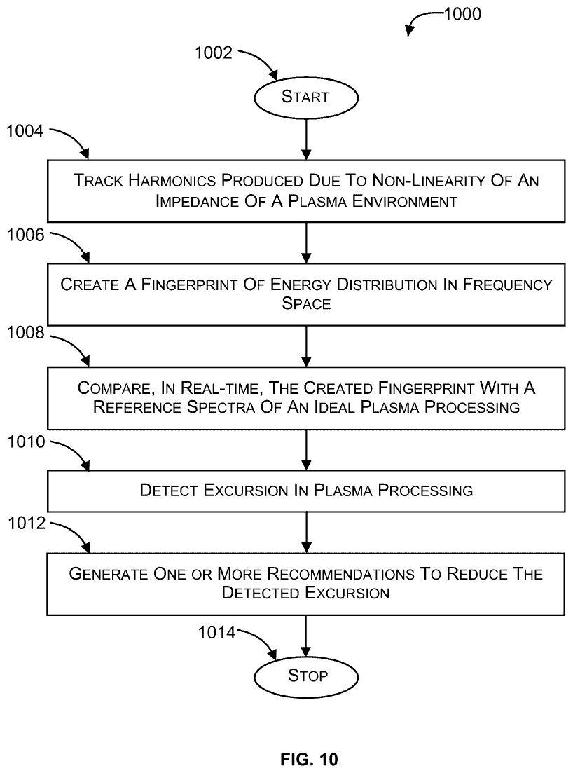

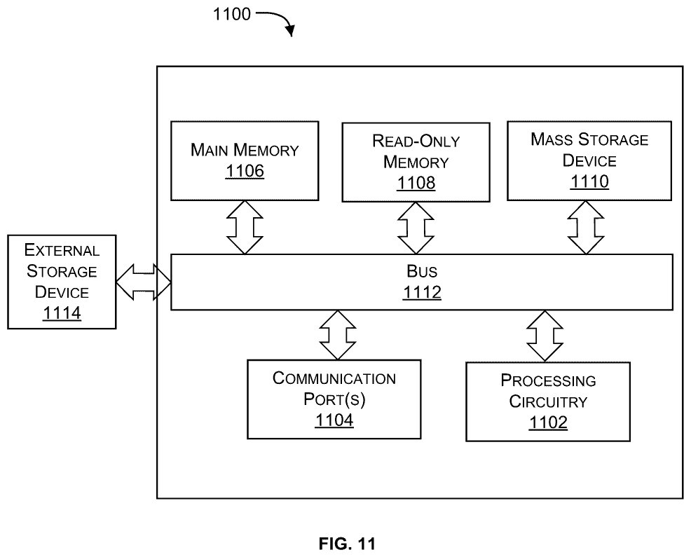

FIG. 10 illustrates a flowchart 1000 of a method for detecting excursion in plasma processing and controlling plasma processing, in accordance with an embodiment of the present disclosure. The method starts at step 1002.

At step 1004, one or more harmonics may be tracked. The one or more harmonics may be associated with voltage, current, or a combination thereof. In an embodiment, a voltage-sensitive transducer and a current-sensitive transducer may be used to track the voltage harmonics and the current harmonics, respectively. It may be understood that the one or more harmonics may be produced due to the nonlinearity of an impedance of a plasma environment. The impedance of the plasma environment is a non-50-ohm impedance, a complex nonlinear impedance, or a combination thereof.

Next, at step 1006, a fingerprint of energy distribution in frequency space may be created based on the tracked one or more harmonics. In an embodiment of the present disclosure, to create the fingerprint, the method further includes the steps of calculating average and standard deviation of amplitude of the one or more harmonics, when plasma and chemical conditions of the plasma processing are stable. Upon calculating the average and standard deviation of the amplitude, the method also includes the steps of filtering the one or more harmonics by removing harmonics from the tracked one or more harmonics that have the amplitude and the standard deviation less than a pre-defined threshold value.

Upon creating the fingerprint, the created fingerprint may be compared with a reference spectra of an ideal plasma processing, stored in a historical database to detect deviation of the fingerprint with the reference spectra, at step 1008. Next, at step 1010, an excursion in the plasma processing may be detected based on the detected deviation of the fingerprint with the reference spectra. In some embodiments, the excursion is detected when the detected deviation is more than a control limit that is associated with the reference spectra.

Thereafter, one or more recommendations may be generated, at step 1012. The one or more recommendations may be generated based on the detected deviation and the associated historical data related to corrective action stored in a corrective action database. The method ends at step 1014.

In an embodiment of the present disclosure, the excursion detection and control system and method disclosed in the present disclosure (for the sake of brevity, hereinafter termed as ‘disclosed mechanism’) accurately detect the excursion in plasma processing. Since the disclosed mechanism utilizes the harmonics generated during plasma processing to detect the excursion in the plasma processing and is independent of the process control inputs such as supplied current or voltage, the disclosed mechanism overcomes the problem of the lack of accuracy due to the dependency on the control inputs. Since the disclosed mechanism provides one or more recommendations related to the reason behind the excursion, the disclosed mechanism facilitates automatic controlling of the excursion in the plasma processing to reduce the excursion and improve the quality of the plasma processing of the substrates.

FIG. 11 illustrates an exemplary computer system in which or with which embodiment of the present disclosure may be utilized. As shown in FIG. 11, a computer system includes an external storage device 1102, a bus 1104, a main memory 1106, a read-only memory 1108, a mass storage device 1110, a communication port 1112, and a processor 1114.

Those skilled in the art will appreciate that computer system 1100 may include more than one processor 1114 and communication ports 1112. Examples of processor 1114 include, but are not limited to, an Intel® Itanium® or Itanium 2 processor(s), or AMD® Opteron® or Athlon MP® processor(s), Motorola® lines of processors, FortiSOC™ system on chip processors or other future processors. Processor 1114 may include various modules associated with embodiments of the present disclosure.

Communication port 1112 can be any of an RS-232 port for use with a modem-based dialup connection, a 10/100 Ethernet port, a Gigabit or 10 Gigabit port using copper or fiber, a serial port, a parallel port, or other existing or future ports. Communication port 1112 may be chosen depending on a network, such as a Local Area Network (LAN), Wide Area Network (WAN), or any network to which the computer system connects.

Memory 1106 can be Random Access Memory (RAM), or any other dynamic storage device commonly known in the art. Read-Only Memory 1108 can be any static storage device(s) e.g., but not limited to, a Programmable Read-Only Memory (PROM) chips for storing static information e.g., start-up or BIOS instructions for processor 1114.

Mass storage 1110 may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 7200 family) or Hitachi (e.g., the Hitachi Deskstar 7K1000), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

Bus 1104 communicatively couples processor(s) 1114 with the other memory, storage, and communication blocks. Bus 1104 can be, e.g., a Peripheral Component Interconnect (PCI)/PCI Extended (PCI-X) bus, Small Computer System Interface (SCSI), USB, or the like, for connecting expansion cards, drives, and other subsystems as well as other buses, such a front side bus (FSB), which connects processor 1114 to a software system.

Optionally, operator and administrative interfaces, e.g., a display, keyboard, and a cursor control device, may also be coupled to bus 1104 to support direct operator interaction with the computer system. Other operator and administrative interfaces can be provided through network connections connected through communication port 1112. An external storage device 1102 can be any kind of external hard-drives, floppy drives, IOMEGA® Zip Drives, Compact Disc—Read-Only Memory (CD-ROM), Compact Disc—Re-Writable (CD-RW), Digital Video Disk—Read Only Memory (DVD-ROM). The components described above are meant only to exemplify various possibilities. In no way should the aforementioned exemplary computer system limit the scope of the present disclosure.

While embodiments of the present disclosure have been illustrated and described, it will be clear that the disclosure is not limited to these embodiments only. Numerous modifications, changes, variations, substitutions, and equivalents will be apparent to those skilled in the art, without departing from the spirit and scope of the disclosure, as described in the claims.

Thus, it will be appreciated by those of ordinary skill in the art that the diagrams, schematics, illustrations, and the like represent conceptual views or processes illustrating systems and methods embodying this disclosure. The functions of the various elements shown in the figures may be provided through the use of dedicated hardware as well as hardware capable of executing associated software. Similarly, any switches shown in the figures are conceptual only. Their function may be carried out through the operation of program logic, through dedicated logic, through the interaction of program control and dedicated logic, or even manually, the particular technique being selectable by the entity implementing this disclosure. Those of ordinary skill in the art further understand that the exemplary hardware, software, processes, methods, and/or operating systems described herein are for illustrative purposes and, thus, are not intended to be limited to any particular named.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously. Within the context of this document terms “coupled to” and “coupled with” are also used euphemistically to mean “communicatively coupled with” over a network, where two or more devices can exchange data with each other over the network, possibly via one or more intermediary device.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc.

While the foregoing describes various embodiments of the disclosure, other and further embodiments of the disclosure may be devised without departing from the basic scope thereof. The scope of the disclosure is determined by the claims that follow. The disclosure is not limited to the described embodiments, versions, or examples, which are included to enable a person having ordinary skill in the art to make and use the disclosure when combined with information and knowledge available to the person having ordinary skill in the art.

We claim:

1. An excursion detection and control system for detecting excursion in plasma processing and controlling an in-situ plasma processing, the excursion detection and control system comprising:
a transducer assembly to:
track one or more harmonics that are produced due to nonlinearity of an impedance in a plasma environment, wherein the one or more harmonics are associated with at least one of: voltage and current;
one or more spectrum analyzers to:
create a fingerprint of energy distribution in frequency space based on the tracked one or more harmonics;
compare, in real-time, the created fingerprint with a reference spectra of an ideal plasma processing, stored in a historical database, to detect deviation of the fingerprint with the reference spectra;
detect an excursion in the plasma processing based on the detected deviation of the fingerprint with the reference spectra; and
a recommendation module to generate one or more recommendations to control the detected excursion, wherein the one or more recommendations are generated based at least on one of: the detected deviation and associated historical data related to corrective action stored in a corrective action database.

2. The excursion detection and control system of claim 1, wherein the one or more spectrum analyzers:
calculate, when plasma and chemical conditions of the plasma processing are stable, at least one of: average and standard deviation of amplitude of the one or more harmonics; and
filter the one or more harmonics by removing harmonics from the tracked one or more harmonics that have the amplitude and the standard deviation less than a pre-defined threshold value.

3. The excursion detection and control system of claim 1, wherein the excursion is detected when the detected deviation is more than a control limit.

4. The excursion detection and control system of claim 3, wherein the control limit is associated with the reference spectra.

5. The excursion detection and control system of claim 1, wherein the deviation is created due to variation in controllable subassemblies of the plasma processing that includes at least one of: incoming workpiece conditions, process chamber pressure, process gas mixture, Radio Frequency (RF) power, and electrode spacing in the process chamber.

6. The excursion detection and control system of claim 1, wherein the recommendation module matches the detected deviation with one or more deviations stored in the corrective action database to determine a reason behind the excursion and provide the one or more recommendations.

7. The excursion detection and control system of claim 1, wherein the one or more recommendations are related to at least one of: controlling workpiece conditions, controlling process chamber pressure, controlling gas mixture, controlling RF power, and controlling electrode spacing.

8. The excursion detection and control system of claim 7, further comprises a controller that performs at least one of:
controlling an associated controllable subassembly based on the one or more recommendations, such that the excursion is reduced in the subsequent substrates; and
stopping the plasma processing based on the detected excursion, such that the subsequent substrates in the plasma processing are saved from the excursion.

9. The excursion detection and control system of claim 1, wherein the plasma processing is performed for at least one of: depositing and removing a film on a substrate, and the reference spectra for comparison with the created fingerprint are selected based on one or more control inputs set by a user for the plasma processing.

10. The excursion detection and control system of claim 9, wherein the one or more control inputs are based on at least one of: purpose of the plasma processing, identification of a type of substrate being used, identification of an amount of substrate being used, identification of a pressure in the process chamber, identification of a type of gas being used, and identification of an amount of gas being used.

11. The excursion detection and control system of claim 1, wherein each of the one or more spectrum analyzers includes any combination of: an RF input attenuator, a pre-selector, a low-pass filter, a local oscillator, a mixer, an Intermediate Frequency (IF) gain module, an IF filter, an analog-to-digital converter, a digital IF, a fast Fourier transform module, a video bandwidth filter, and a display, working in tandem.

12. An excursion detection and control system for detecting excursion in a downstream plasma processing and controlling downstream plasma processing, the excursion detection and control system comprising:
an electrode assembly inserted in an exhaust line of a plasma processing chamber to receive its effluent as a feed gas;
a power generator to generate an energy for ionizing the received feed gas in the electrode assembly, wherein the ionization of the feed gas leads to a formation of a plasma environment to create a small capacitively coupled plasma;
a dual directional coupler coupled between the electrode assembly and the power generator to track one or more harmonics that are produced due to non-linearity of an impedance in the plasma environment, wherein the one or more harmonics are associated with at least one of: voltage and current;
one or more spectrum analyzers to:
create a fingerprint of energy distribution in frequency space based on the tracked one or more harmonics;
compare, in real-time, the created fingerprint with a reference spectra of an ideal plasma processing, stored in a historical database, to detect deviation of the fingerprint with the reference spectra;
detect an excursion in the plasma processing based on the detected deviation of the fingerprint with the reference spectra; and
a recommendation module to generate one or more recommendations to control the detected excursion, wherein the one or more recommendations are generated based at least on one of: the detected deviation and associated historical data related to corrective action stored in a corrective action database.

13. The excursion detection and control system of claim 12, wherein the one or more spectrum analyzers:
calculate, when plasma and chemical conditions of the plasma processing are stable, at least one of: average and standard deviation of amplitude of the one or more harmonics; and
filter the one or more harmonics by removing harmonics from the tracked one or more harmonics that have the amplitude and the standard deviation less than a pre-defined threshold value.

14. The excursion detection and control system of claim 12, wherein the excursion is detected when the detected deviation is more than a control limit.

15. The excursion detection and control system of claim 14, wherein the control limit is associated with reference spectra.

16. The excursion detection and control system of claim 1, wherein the recommendation module matches the detected deviation with one or more deviations stored in the corrective action database to determine a reason behind the excursion and provide the one or more recommendations, wherein the one or more recommendations are related to at least one of: controlling workpiece conditions, controlling process chamber pressure, controlling gas mixture, controlling RF power, and controlling electrode spacing.

17. The excursion detection and control system of claim 16, further comprises a controller that performs at least one of:
controlling an associated controllable subassembly based on the one or more recommendations, such that the excursion is reduced in the subsequent substrates; and
stopping the plasma processing based on the detected excursion, such that the subsequent substrates in the plasma processing are saved from the excursion.

18. An method for detecting excursion in plasma processing and controlling plasma processing, the method comprising:
tracking one or more harmonics that are produced due to nonlinearity of an impedance of a plasma environment, wherein the one or more harmonics are associated with at least one of: voltage and current;
creating a fingerprint of energy distribution in frequency space based on the tracked one or more harmonics;
comparing, in real-time, the created fingerprint with a reference spectra of an ideal plasma processing, stored in a historical database, to detect deviation of the fingerprint with the reference spectra;
detecting an excursion in the plasma processing based on the detected deviation of the fingerprint with the reference spectra; and
generating one or more recommendations to control the detected excursion, wherein the one or more recommendations are generated based at least on one of: the detected deviation and the associated historical data related to corrective action stored in a corrective action database.

19. The method of claim 18, further comprises:
calculating, when plasma and chemical conditions of the plasma processing are stable, at least one of: average and standard deviation of amplitude of the one or more harmonics; and
filtering the one or more harmonics by removing harmonics from the tracked one or more harmonics that have the amplitude and the standard deviation less than a pre-defined threshold value.

20. The method of claim 18, wherein the excursion is detected with the detected deviation is more than a control limit, wherein the control limit is associated with the reference spectra.
